(19) United States
(12) Patent Application Publication
(10) Pub. No.: US 2017/0064814 A1
(43) Pub. Date: Mar. 2, 2017

(54) SIGNAL WIRING BOARD

(71) Applicant: FUJITSU LIMITED, Kawasaki-shi (JP)

(72) Inventor: Tomohiro Kawaguchi, Kamakura (JP)

(73) Assignee: FUJITSU LIMITED, Kawasaki-shi (JP)

(21) Appl. No.: 15/205,482

(22) Filed: Jul. 8, 2016

(30) Foreign Application Priority Data
Sep. 2, 2015 (JP) 2015-173302

(51) Int. Cl. H05K 1/02; H05K 1/11

(52) U.S. Cl. CPC H05K 1/0216; H05K 1/0298; H05K 1/115

(57) ABSTRACT

A signal wiring board includes: a base material; a plurality of signal wiring layers extending in a fixed extending direction and being arranged so as to be spaced in a thickness direction of the base material; and at least one coupling unit that electrically couples a plurality of the signal wiring boards.

### CROSS-REFERENCE TO RELATED APPLICATION

This application is based upon and claims the benefit of priority of the prior Japanese Patent Application No. 2015-173302, filed on Sep. 2, 2015, the entire contents of which are incorporated herein by reference.

### FIELD

The embodiments discussed herein are related to signal wiring boards.

### BACKGROUND

There is a dielectric waveguide line in which a pair of conductive layers is formed at positions for sandwiching a dielectric board having a given thickness, and a large number of via holes that electrically couple the conductive layers are arranged between the conductive layers. This dielectric waveguide line includes a sub-conductive layer between the main conductive layers. The sub-conductive layer is coupled to via holes forming a sidewall of the waveguide line and is formed parallel to the main conductive layers.

There is also a suspension with a circuit for a magnetic head. In the suspension, a load beam unit includes a sheet-shaped insulating layer and a plurality of circuits made of a conductor. These circuits are formed in a multilayer structure, in which an insulator is interposed between the circuits.

In a signal wiring board that allows electrical signals to flow to a signal wiring layer, it is desirable that the transmission loss be reduced.

For example, it is conceivable to increase the width or thickness of a signal wiring layer to reduce the transmission loss.

However, with a structure for increasing the width of a signal wiring layer, increasing the wiring line interval, in addition to the width of the wiring line itself, leads to a decrease in wiring density.

With a structure for increasing the thickness of a signal wiring layer, if, compared to the width of a signal wiring layer, the thickness is excessively large, pattern formation of the signal wiring layer becomes difficult.

The following are reference documents. [Document 1] Japanese Laid-open Patent Publication No. 10-75108 and [Document 2] Japanese Laid-open Patent Publication No. 2003-162804.

### SUMMARY

According to an aspect of the invention, a signal wiring board includes: a base material; a plurality of signal wiring layers extending in a fixed extending direction and being arranged so as to be spaced in a thickness direction of the base material; and at least one coupling unit that electrically couples a plurality of the signal wiring boards.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view partially illustrating a signal wiring board of a first embodiment;

FIG. 2 is a sectional view taken along the line 2-2 in FIG. 1 partially illustrating the signal wiring board of the first embodiment;

FIG. 3 is a sectional view partially illustrating signal wiring layers of the signal wiring board of the first embodiment;

FIG. 4 is a sectional view illustrating a state in which the signal wiring board of the first embodiment is being manufactured;

FIG. 5 is a sectional view illustrating a state in which the signal wiring board of the first embodiment is being manufactured;

FIG. 6 is a sectional view illustrating a state in which the signal wiring board of the first embodiment is being manufactured;

FIG. 7 is a sectional view illustrating a state in which the signal wiring board of the first embodiment is being manufactured;

FIG. 8 is a sectional view illustrating a state in which the signal wiring board of the first embodiment is being manufactured;

FIG. 9 is a sectional view illustrating a state in which the signal wiring board of the first embodiment is being manufactured;

FIG. 10 is a sectional view illustrating a state in which the signal wiring board of the first embodiment is being manufactured;

FIG. 11 is a sectional view partially illustrating a signal wiring board of a first comparative example;

FIG. 12 is a sectional view partially illustrating a signal wiring board of a second comparative example;

FIG. 13 is a sectional view partially illustrating a signal wiring board of a third comparative example;

FIG. 14 is a graph qualitatively illustrating the relationship between the signal frequency and the transmission loss characteristics;

FIG. 15 is a graph qualitatively illustrating the relationship between the signal frequency and the transmission loss characteristics;

FIG. 16 is a sectional view partially illustrating signal wiring layers of a signal wiring board of a second embodiment;

FIG. 17 is a perspective view partially illustrating signal wiring layers of a signal wiring board of a third embodiment;

FIG. 18 is a perspective view partially illustrating signal wiring layers of a signal wiring board of a fourth embodiment;

FIG. 19 is a perspective view partially illustrating signal wiring layers of a signal wiring board of a fifth embodiment; and

FIG. 20 is a perspective view partially illustrating signal wiring layers of a signal wiring board of a sixth embodiment.

### DESCRIPTION OF EMBODIMENTS

A signal wiring board of a first embodiment will be described in detail with reference to the accompanying drawings. This signal wiring board is sometimes used, for example, as a transmission path (line), such as peripheral component interconnect (PCI) Express or universal serial bus (USB), which transmits differential high-speed signals.

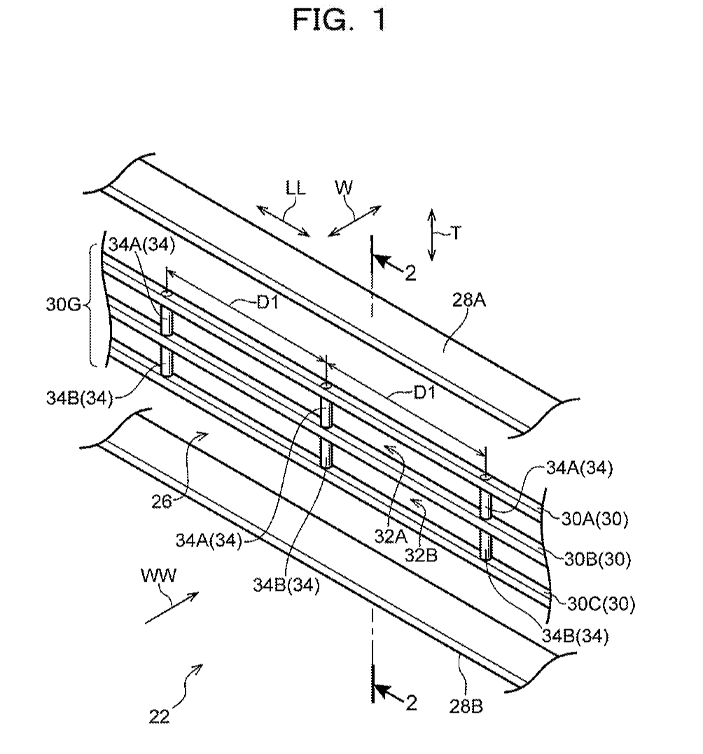

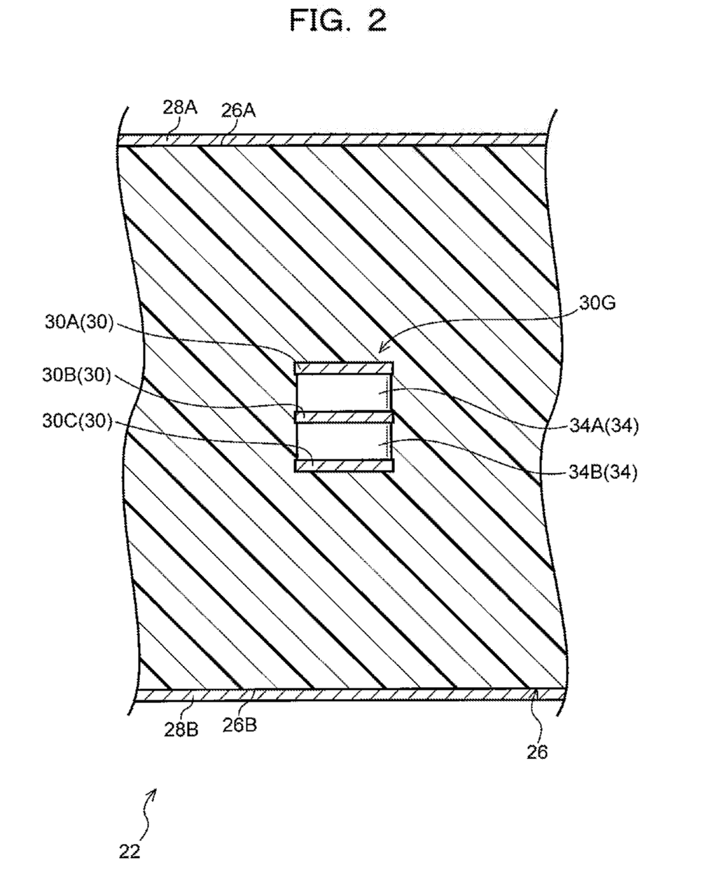

As illustrated in FIG. 1 and FIG. 2, a signal wiring board 22 of the first embodiment includes a plate-shaped base material 26. The base material 26 is formed of a material having insulation properties. Specific examples of the material of the base material 26 include, but not limited to, ceramic, glass epoxy, and polyimide. The thickness direction of the base material 26 is indicated by an arrow T.

A ground wiring line 28A is formed on one end surface 26A in the thickness direction of the base material 26, and a ground wiring line 28B is formed on the other end surface 26B. Note that although the wiring lines of the end surfaces 26A and 26B in the thickness direction of the base material 26 are described for convenience as ground wiring lines 28A and 28B, these wiring lines may be power supply wiring lines.

Inside the base material 26, a plurality of signal wiring layers 30 are formed so as to be spaced in the thickness direction of the base material 26. Further, a signal wiring group 30G is formed of the plurality of signal wiring layers 30. In the present embodiment, the signal wiring layers 30 are three layers, which are appropriately identified as signal wiring layers 30A, 30B, and 30C from the side of the end surface 26A. The signal wiring group 30G formed in such a manner (the signal wiring layers 30 in a plural-layer structure), a plurality of which are consecutively arranged in the width direction (an arrow X W direction) in the base material 26, is used for transmission of differential signals.

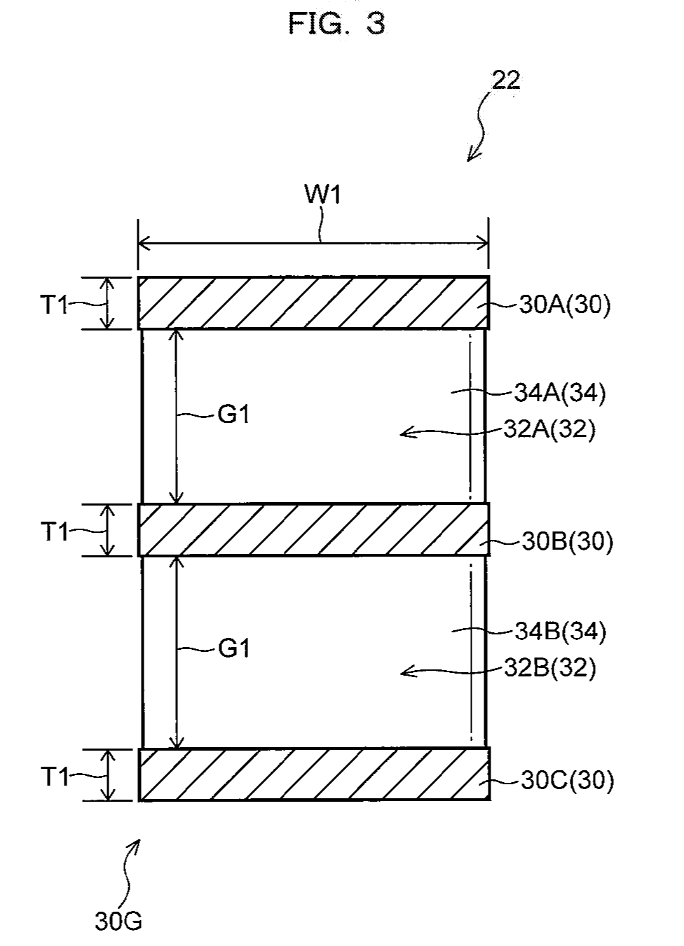

As illustrated in FIG. 3, every one of the signal wiring layers 30 has a given width W1 (for example, 0.160 mm) and a thickness T1 (for example, 18 μm). Further, all the signal wiring layers 30 extend in the same direction, and the three signal wiring layers 30A, 30B, and 30C are parallel to one another. The signal wiring layers 30 are arranged apart in the thickness direction such that clearances 32A and 32B each having a given length G1 (for example, 60 μm) are created between the signal wiring layers 30A and 30B and between the signal wiring layers 30B and 30C.

Vias 34 are formed between the signal wiring layers 30. Hereinafter, a via between the signal wiring layers 30A and 30B is referred to as a via 34A, and a via between the signal wiring layers 30B and 30C is referred to as a via 34B, so that the vias are appropriately identified. By the via 34A, the signal wiring layer 30A and the signal wiring layer 30B are electrically coupled. By the via 34B, the signal wiring layer 30B and the signal wiring layer 30C are electrically coupled.

As illustrated in FIG. 1, in the present embodiment, the number of the vias 34A or 34B is three or more. Further, the via 34A and the via 34B are located at the same position in the longitudinal direction (an arrow LL direction) of the signal wiring layers 30. The vias 34A or 34B are formed with given intervals D1 (for example, 5.0 mm) in the longitudinal direction of the signal wiring layer 30. As the signal wiring board 22 is viewed in an arrow WW direction, the signal wiring layers 30A, 30B, and 30C and the vias 34A and 34B are considered to form a lattice structure.

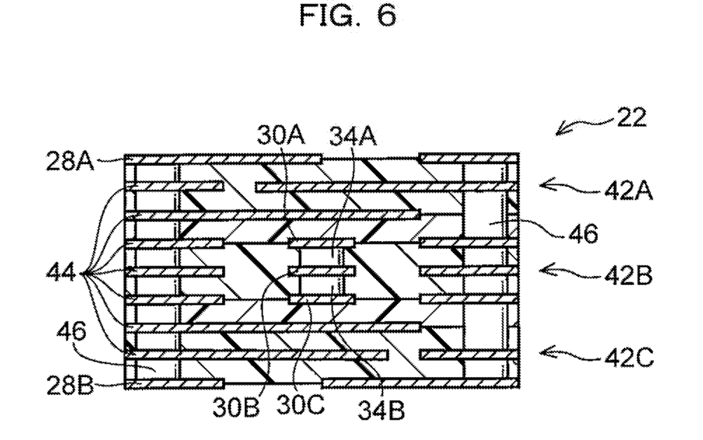

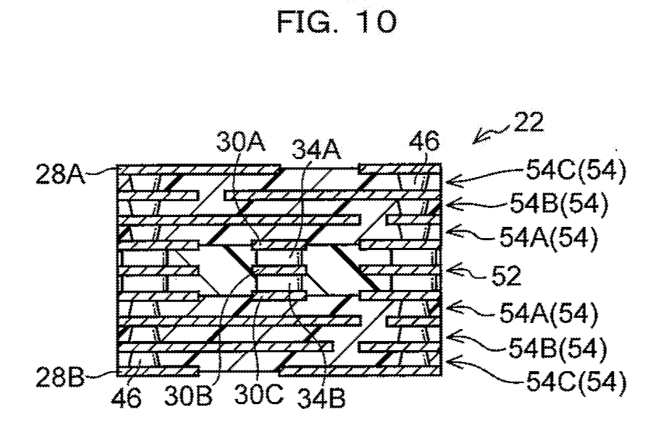

Note that, although not illustrated in FIG. 1 and FIG. 2, wiring layers 44 other than the signal wiring layers 30 and through-vias 46 passing through the entirety of the signal wiring board 22 in its thickness direction may be formed in the base material 26 as illustrated in FIG. 6 and FIG. 10.

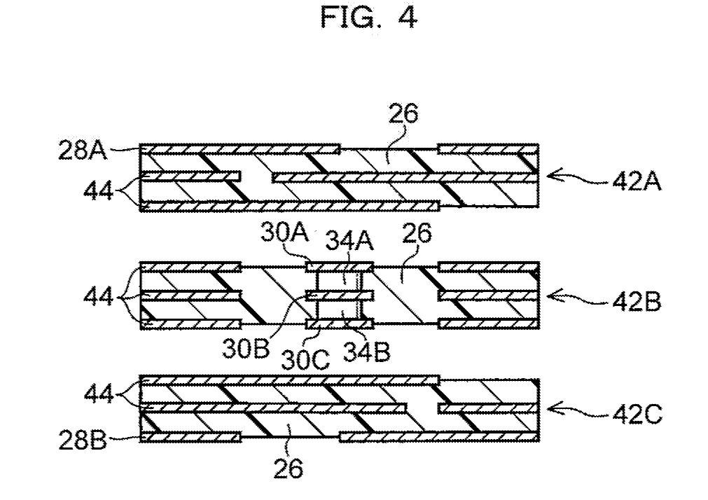

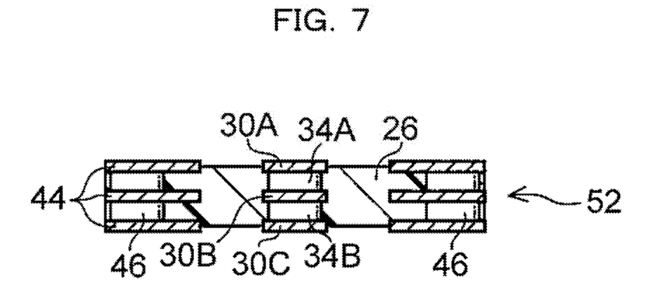

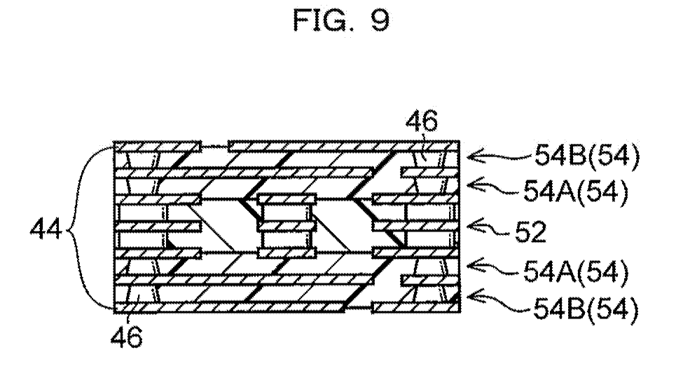

A method for manufacturing the signal wiring board 22 is not particularly limited. For example, the signal wiring board 22 may be manufactured by a manufacturing method illustrated in FIG. 4 to FIG. 6 (hereinafter referred to as a “first manufacturing method”) or by a manufacturing method illustrated in FIG. 7 to FIG. 10 (hereinafter referred to as a “second manufacturing method”).

The first manufacturing method is a method that bonds a plurality of board materials together to manufacture the signal wiring board 22, and the manufactured board is referred to as a “bonded board” in some cases.

In the first manufacturing method, first, as illustrated in FIG. 4, three board materials 42A, 42B, and 42C are manufactured. The board materials 42A, 42B, and 42C are bonded together to form the signal wiring board 22. In the board material 42B located at the center in the stacking direction in the bonded state (refer to FIG. 6), the signal wiring layers 30A, 30B, and 30C and vias 34A and 34B are formed. Note that, in FIG. 4 to FIG. 6, the wiring layers 44 formed in each of the board materials 42A, 42B, and 42C are also illustrated.

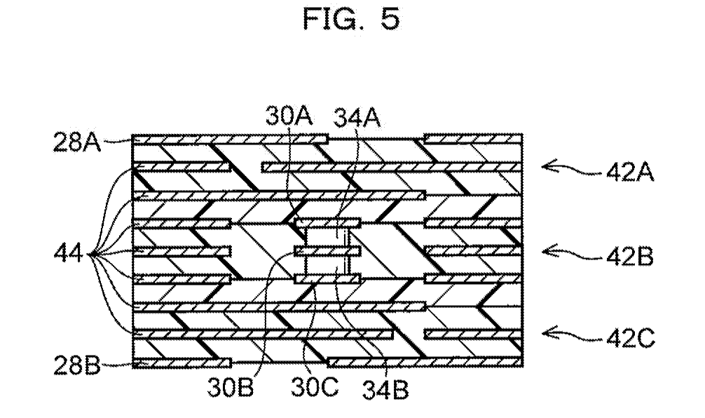

Further, as illustrated in FIG. 5, three board materials 42A, 42B, and 42C are bonded together. Subsequently, as illustrated in FIG. 6, the through-vias 46 passing through the entirety of the signal wiring board 22 are formed.

In the first manufacturing method, the number of board materials bonded together may be four or more. Further, the board material in which the signal wiring layers 30A, 30B, and 30C and the vias 34A and 34B are formed is not limited as long as it is a board material located in the inner side (for example, the second or third board material when four board materials are used) in the bonding direction.

In contrast, the second manufacturing method is a method that sequentially builds up layers of the signal wiring board 22, and the manufactured board is referred to as a “build-up board” in some cases.

In the second manufacturing method, first, as illustrated in FIG. 7, a core layer 52 is formed. In the base material 26 of the core layer 52, the signal wiring layers 30A, 30B, and 30C and the vias 34A and 34B are formed. Additionally, the wiring layers 44 and the through-vias 46 are also formed in the core layer 52.

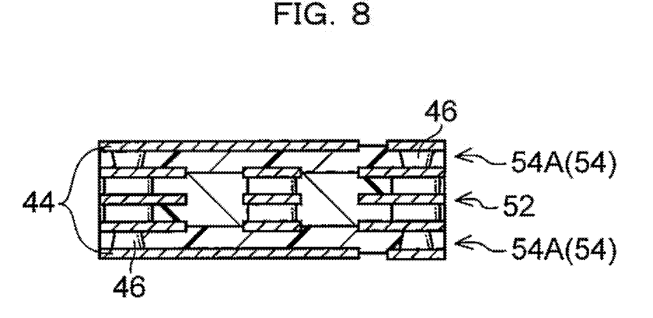

A plurality of build-up layers 54 is stacked on both the surfaces of the core layer 52. In the example illustrated in FIG. 8 to FIG. 10, build-up first layers 54A, build-up second layers 54B, and build-up third layers 54C are sequentially stacked. Note that the wiring layers 44 and the through-vias 46 are formed in these build-up first layers 54A, the build-up second layers 54B, and the build-up third layers 54C.

In the second manufacturing method, the signal wiring layers 30A, 30B, and 30C and the vias 34A and 34B may be formed in the build-up first layer 54A or the build-up second layer 54B.

Next, operations of the present embodiment will be described.

The signal wiring board 22, including a plurality of signal wiring layers 30, allows the same electrical signal to flow to these signal wiring layers 30. That is, it is possible to cause one signal to flow separately to the plurality of signal wiring layers 30.

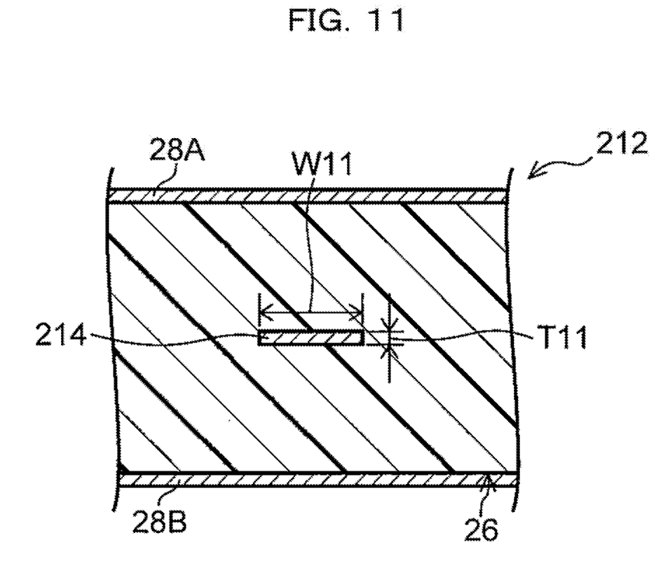

Here, FIG. 11 illustrates a signal wiring board 212 of a first comparative example. The signal wiring board 212 of the first comparative example includes a signal wiring layer 214 formed of a single layer. A width W 11 and a thickness T11 of this signal wiring layer 214 are the same as the width W1 and the thickness T1 of the signal wiring layer 30 in the signal wiring board 22 of the first embodiment.

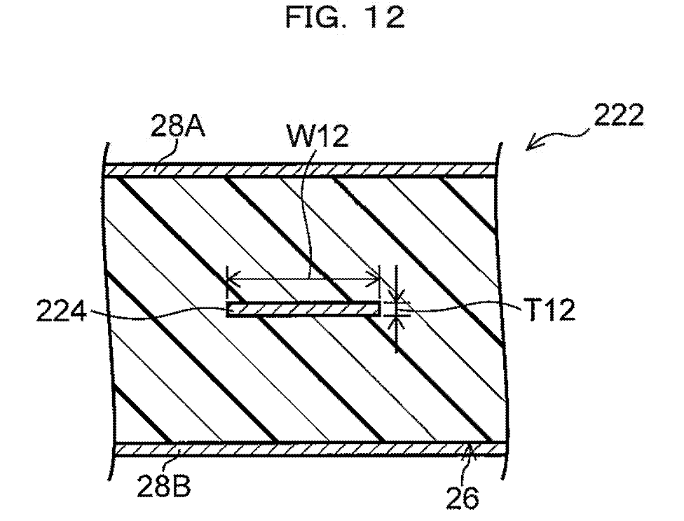

FIG. 12 illustrates a signal wiring board 222 of a second comparative example. The signal wiring board 222 of the second comparative example includes a signal wiring layer 224 formed of a single layer. A width W12 of the signal wiring layer 224 is larger (for example, 0.240 mm) than the width W1 of the signal wiring layer 30 of the first embodiment. A thickness T12 of the signal wiring layer 224 of the second comparative example is the same as the thickness T1 of the signal wiring layer 30 of the first embodiment.

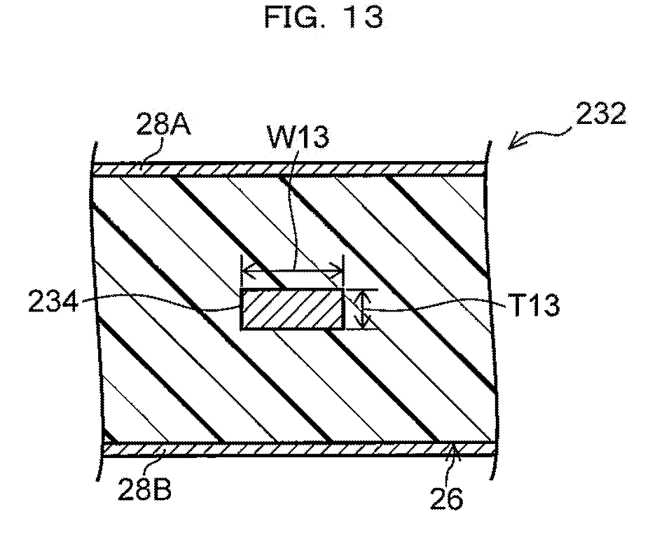

FIG. 13 illustrates a signal wiring board 232 of a third comparative example. The signal wiring board 232 of the third comparative example includes a signal wiring layer 234 formed of a single layer. A width W13 of this signal wiring layer 234 is the same as the width W1 of the signal wiring layer 30 of the first embodiment. A thickness T13 of the signal wiring layer 234 of the third comparative example is larger (for example, 70 μm) than the thickness T1 of the signal wiring layer 30 of the first embodiment.

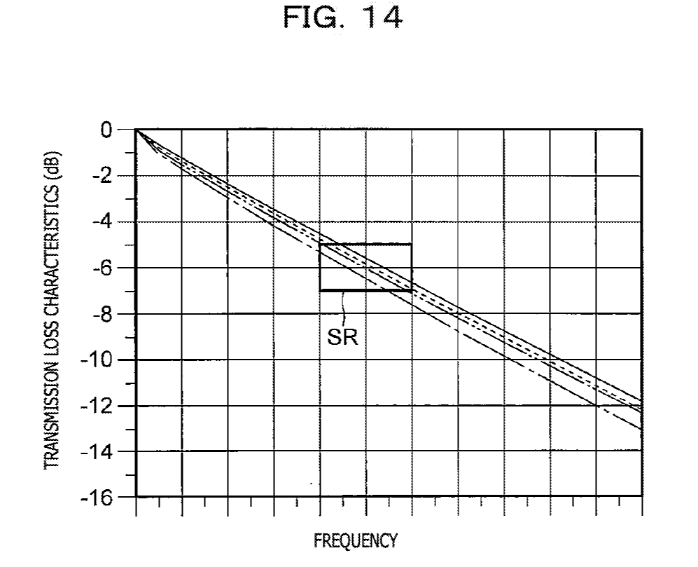

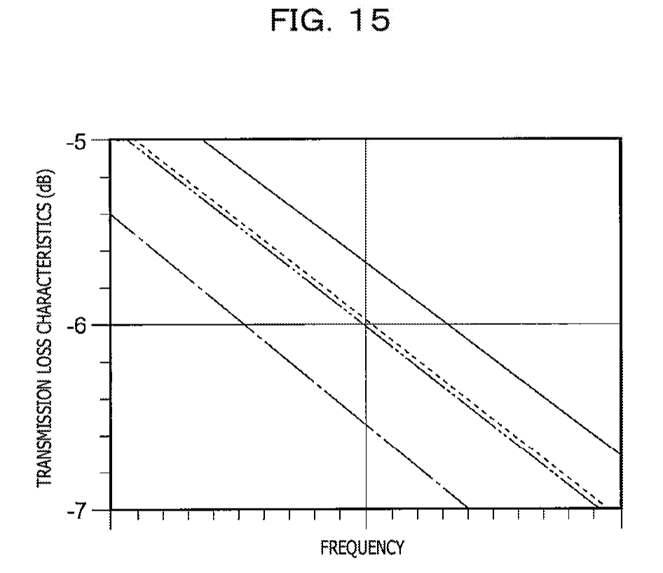

FIG. 14 and FIG. 15 qualitatively illustrate transmission loss characteristics in the signal wiring boards of the first embodiment and the first to third comparative examples. In particular, FIG. 15 is a graph in which the range surrounded by a box SR in FIG. 14 is enlarged. In these graphs, the solid line corresponds to the first embodiment, the alternate long and short dashed line to the first comparative example, the chain double-dashed line to the second comparative example, and the broken line to the third comparative example. In these graphs, the higher the position, the better the transmission loss characteristics.

As seen from the graphs, the signal wiring board 22 of the first embodiment is better in terms of transmission loss characteristics than any of the signal wiring boards 212, 222, and 232 of the first to third comparative examples.

In particular, compared to the signal wiring board 212 of the first comparative example, the transmission loss is greatly improved in the signal wiring board 22 of the first embodiment. The signal wiring board 22 of the first embodiment includes the signal wiring layers 30 formed of a plurality of layers (three layers), and therefore has a larger surface area of portions where signals flow, than the signal wiring boards 212, 222, and 232 of the first to third embodiments. That is, in the signal wiring board 22 of the first embodiment, the skin effect is very pronounced.

The width W12 of the signal wiring layer 224 of the signal wiring board 222 of the second comparative example is larger than the width of the signal wiring layer 30 of the signal wiring board 22 of the first embodiment and therefore is disadvantageous in terms of formation of the signal wiring layers 30 at high density. In the signal wiring board 22 of the first embodiment, the width W1 of the signal wiring layer 30 (refer to FIG. 3) is smaller than in the second comparative example and therefore is advantageous in terms of formation of the signal wiring layers 30 at high density.

In the signal wiring board 232 of the third comparative example, since the thickness T13 of the signal wiring layer 234 is large, formation of the signal wiring layer 234 (pattern formation) is sometimes difficult when the signal wiring board 232 is actually manufactured. In the signal wiring board 22 of the first embodiment, since the thickness T1 of the signal wiring layer 30 is smaller than in the third comparative example, formation of the signal wiring layers 30 (pattern formation) is easy.

In such a way, the signal wiring board 22 of the present embodiment allows the transmission loss to be reduced without increasing the width and the thickness of the signal wiring layer 30.

Further, reducing the transmission loss for signals transmitted or received by the signal wiring board 22 enables the transmission of the signals to be speeded up as compared to a structure having a large transmission loss.

The signal wiring board 22 of the first embodiment includes vias 34. By the vias 34, a plurality of signal wiring layers 30 are electrically coupled. Therefore, if imbalance occurs in the currents flowing through respective ones of the signal wiring layers 30, the imbalance may be reduced owing to the vias 34.

In the signal wiring board 22 of the first embodiment, three or more vias 34 are formed so as to be spaced at equal intervals D1 in the extending direction of the signal wiring layers 30. The fixed interval D1 between the vias 34 in such a manner allows the effect of reduced imbalance in the currents flowing through the signal wiring layers 30 to be pronounced.

In the signal wiring board 22, the ground wiring lines 28A and 28B are formed on the end surfaces (the end surface 26A and the end surface 26B) in the thickness direction of the base material 26. Thus, radiation of electromagnetic waves from signals flowing through the signal wiring layers 30 may be controlled and the characteristics impedances may be effectively matched over the entirety of the signal wiring board 22.

Note that, if the ground wiring line 28A is formed on one end surface (either the end surface 26A or the end surface 26B) in the thickness direction of the base material 26, the characteristics impedances may be matched compared to a structure without the ground wiring line 28A. In this case, since the ground wiring line 28A is formed on one end surface in the thickness direction of the base material 26, structure simplification and thickness reduction of the signal wiring board may be achieved compared to the case of a structure in which ground wiring lines are formed on both the end surfaces.

Next, a second embodiment will be described. In the second embodiment, the same elements, members, and the like as those in the first embodiment are denoted by the same reference characters, and the detailed description thereof is omitted. Additionally, the entire structure of the signal wiring board 62 of the second embodiment is similar to that of the signal wiring board 22 of the first embodiment and therefore is not illustrated in the drawing.

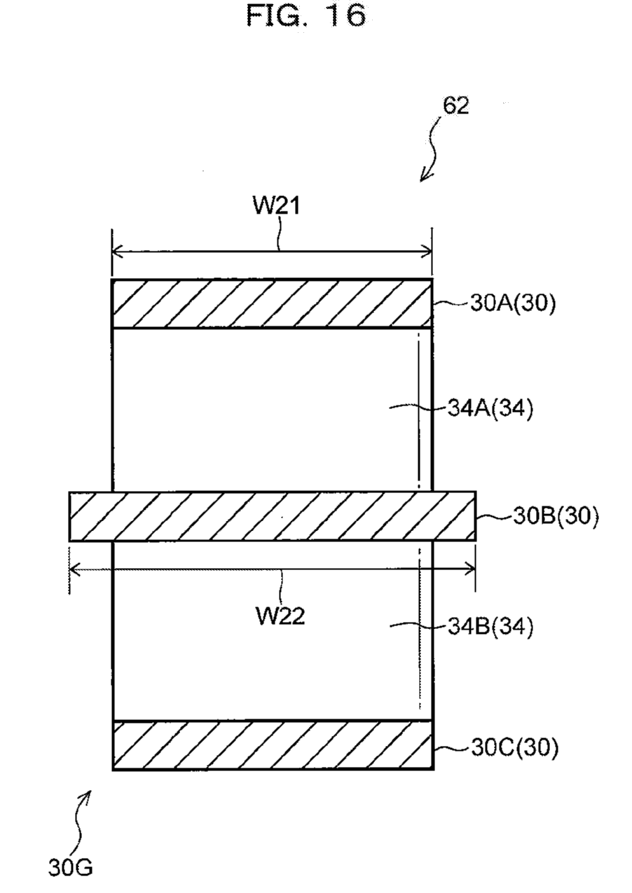

As illustrated in FIG. 16, in the second embodiment, among a plurality of signal wiring layers 30, part of the signal wiring layers has a width different from that of the other signal wiring layers. In the example of FIG. 16, a width W22 (for example, 0.180 mm) of a signal wiring layer 30B located in the center of the signal wiring layers 30 is larger than a width W21 (for example, 0.140 mm) of the other signal wiring layers 30A and 30C.

In such a manner, in the plurality of signal wiring layers 30, part of the signal wiring layers is caused to have a width different from the width of the other signal wiring layers. This makes it possible for the signal wiring layers 30 with suitable widths to be arranged even when the wiring conditions vary depending on the position of each signal wiring layer.

Next, a third embodiment will be described. In the third embodiment, the same elements, members, and the like as those in the first embodiment are denoted by the same reference characters, and the detailed description thereof is omitted. Additionally, the entire structure of the signal wiring board 72 of the third embodiment is similar to that of the signal wiring board 22 of the first embodiment and therefore is not illustrated in the drawing.

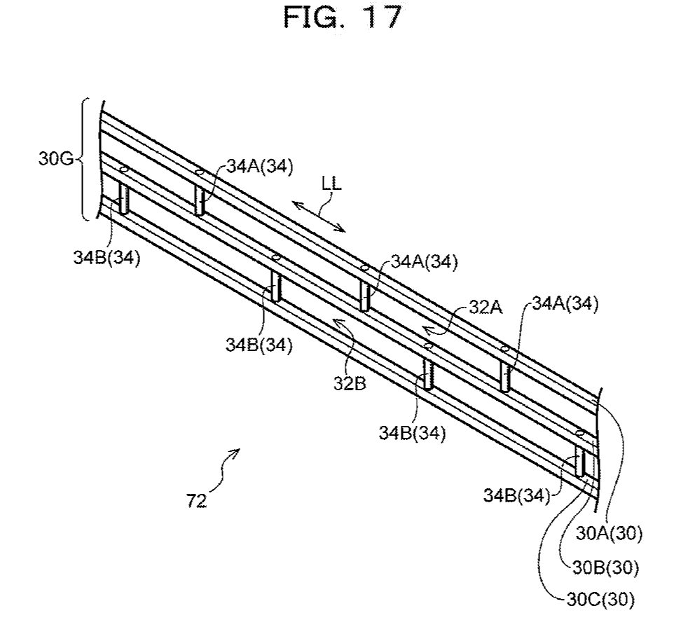

As illustrated in FIG. 17, in the third embodiment, the positions of the vias 34A and 34B are different between a clearance 32A of the signal wiring layers 30A and 30B and a clearance 32B of the signal wiring layers 30B and 30C. In the example of FIG. 17, the vias 34A are located midway between a plurality of vias 34B in the extending direction (the arrow LL direction) of the signal wiring layers 30.

In such a manner, the positions of the vias 34A and 34B are caused to be different by using the clearances of the signal wiring layers 30, and thus the signal wiring layer 30B is located on the lower-side via 34B. For example, during manufacturing of the signal wiring board 72 by building-up, if an upper-side via 34A is formed directly above the lower-side via 34B, hole filling has to be performed in some cases so that no hole is left in the lower-side via 34B. However, in some cases, such hole filling causes a change in the electrical characteristics of the lower-side via 34B. In the third embodiment, since hole filling does not have to be performed for the lower-side vias 34B, manufacturing is easy and the change in the electrical characteristics of the lower-side vias 34B may be inhibited.

Next, a fourth embodiment will be described. In the fourth embodiment, the same elements, members, and the like as those in the first embodiment are denoted by the same reference characters, and the detailed description thereof is omitted. The entire structure of the signal wiring board 82 of the fourth embodiment is similar to that of the signal wiring board 22 of the first embodiment and therefore is not illustrated in the drawing.

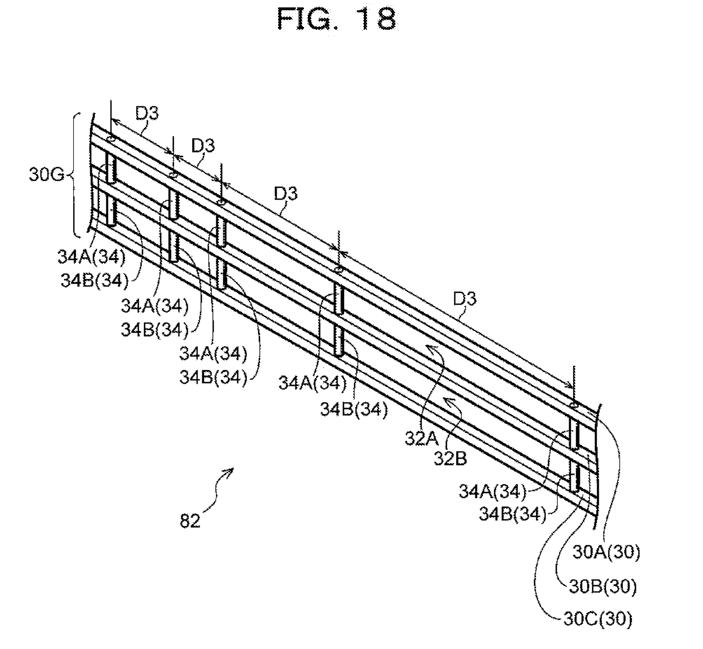

As illustrated in FIG. 18, in the fourth embodiment, the number of vias 34A or 34B is three or more. Further, the positions of the vias 34A and 34B are the same between the clearance 32A of the signal wiring layers 30A and 30B and the clearance 32B of the signal wiring layers 30B and 30C; however, intervals D3 between the vias 34A or 34B vary in the extending direction (the arrow LL direction) of the signal wiring layers 30.

In such a manner, the intervals D3 of the vias 34A or 34B are caused to vary in the extending direction of the signal wiring layers 30. This makes it possible to decrease the numbers of vias 34A or 34B while maintaining the electrical characteristics of the entirety of the signal wiring layers 30. If the number of via holes formed during manufacturing is decreased by decreasing the numbers of vias 34A or 34B, manufacturing of the signal wiring board 82 is easy.

Next, a fifth embodiment will be described. In the fifth embodiment, the same elements, members, and the like as those in the first embodiment are denoted by the same reference characters, and the detailed description thereof is omitted. The entire structure of a signal wiring board 92 of the fifth embodiment is similar to that of the signal wiring board 22 of the first embodiment and thus is not illustrated in the drawing.

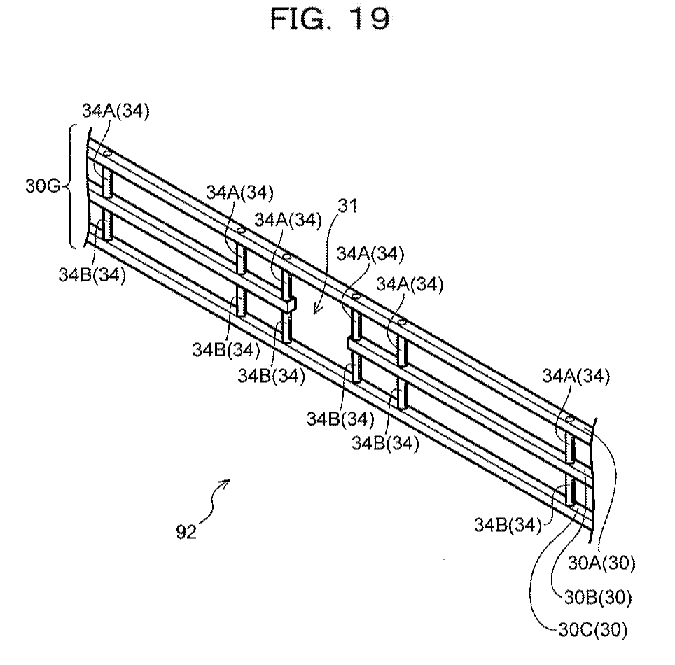

As illustrated in FIG. 19, in the fifth embodiment, the number of layers varies in part in the extending direction of the signal wiring layers 30. In the example of FIG. 19, the signal wiring layer 30B is split at its middle portion, and the number of layers in the signal wiring layers 30 is two at this split location 31

In such a manner, even though there is a location with a varied number of layers in the signal wiring layers 30, the signal wiring layers 30 only have to be such that the entirety of the signal wiring layers 30 has desired characteristics.

Next, a sixth embodiment will be described. In the sixth embodiment, the same elements, members, and the like as those in the first embodiment are denoted by the same reference characters, and the detailed description thereof is omitted. Additionally, the entire structure of the signal wiring board 102 of the sixth embodiment is similar to that of the signal wiring board 22 of the first embodiment and therefore is not illustrated in the drawing.

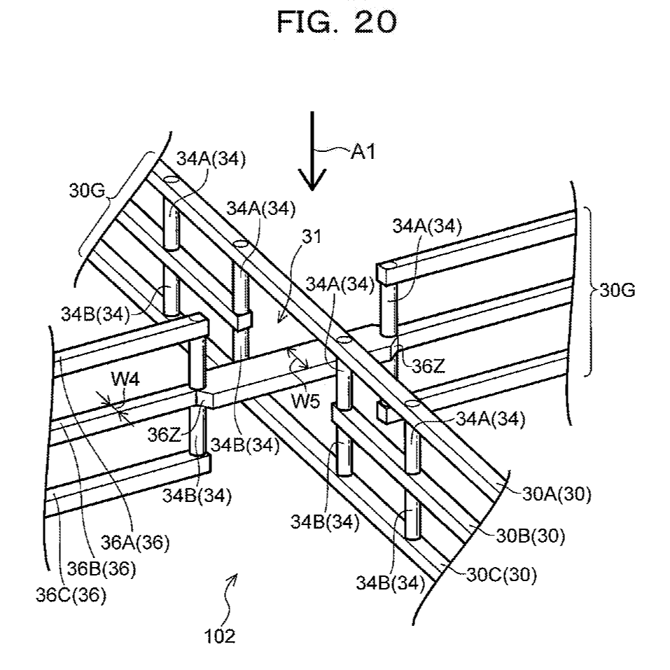

As illustrated in FIG. 20, in the sixth embodiment, as in the fifth embodiment, the signal wiring layer 30B that is split at its middle portion in the extending direction is included.

Further, in the sixth embodiment, in addition to the signal wiring layers 30A, 30B, and 30C, three signal wiring layers 36 (specifically, the signal wiring layers 36A, 36B, and 36C) are included. All the signal wiring layers 36 extend in an orientation in which they are perpendicular to the signal wiring layers 30 as viewed in an arrow A1 direction. However, the signal wiring layers 36A and 36C are split at their middle portions in the extending direction. Therefore, the signal wiring layer 36A is not in contact with the signal wiring layer 30A, and the signal wiring layer 36C is not in contact with the signal wiring layer 30C. In contrast, the signal wiring layer 36B passes through the split location 31 of the signal wiring layer 30B. In the example illustrated in FIG. 20, the signal wiring layer 36B may be considered to be at a “skew position” with respect to the signal wiring layers 30A and 30C.

In such a manner, the number of layers is decreased at a location of part in the extending direction of the signal wiring layers 30, and thus part of other signal wiring layers is enabled to pass through this location with the decreased number of layers (the split location 31 at which the signal wiring layers 30 are split). The flexibility in arrangement of the signal wiring layers 30 is high.

In the example illustrated in FIG. 20, the signal wiring layer 36B is formed in an orientation in which it is perpendicular to the signal wiring layers 30A and 30C as viewed in the arrow A1 direction. Thus, cross-talks between the signal wiring layers 30A and 30C and the signal wiring layer 36B may be reduced. In particular, at the split location 31, the signal wiring layer 36B is located at equal distances from the signal wiring layers 30A and 30C and therefore may reduce cross talks more effectively than in the case where the signal wiring layer 36B is arranged so as to be biased toward either of the signal wiring layers 30A and 30C.

In the example illustrated in FIG. 20, at a location where the signal wiring layers 36A and 36C are split, a width W5 of the signal wiring layer 36B is larger than a width W4 at the other locations of the signal wiring layer 36B. This reduces a local change in the electrical resistance (or impedance) at a portion where the number of layers in the signal wiring layers 36 is locally decreased.

In addition, the signal wiring layer 36B includes width gradual increase sections 36Z in each of which the width gradually increases from a portion with the width W4 (small width) to a portion with the width W5 (large width). This may inhibit a sudden change in impedance that occurs as the width (cross section) of the signal wiring layer 36B suddenly changes.

Although, in each of the embodiments described above, the via 34 is mentioned as an example of a coupling unit, the coupling unit is not limited to the via 34 if it is capable of electrically coupling the signal wiring layers 30.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A signal wiring board comprising:
a base material;
a plurality of signal wiring layers extending in a fixed extending direction and being arranged so as to be spaced in a thickness direction of the base material; and
at least one coupling unit that electrically couples a plurality of the signal wiring boards.

2. The signal wiring board according to claim 1, further comprising
a ground layer arranged at an end in the thickness direction of the base material.

3. The signal wiring board according to claim 2, wherein
the ground layer is arranged at each of both ends in the thickness direction of the base material.

4. The signal wiring board according to claim 1, wherein
a layer width of a first one of a plurality of the signal wiring layers is different from a layer width of a second one of the signal wiring layers.

5. The signal wiring board according to claim 1, wherein
the at least one coupling unit includes three or more coupling units spaced at equal intervals in the extending direction.

6. The signal wiring board according to claim 1, wherein the at least one coupling unit includes three or more coupling units spaced at different intervals in the extending direction.

7. The signal wiring board according to claim 1, wherein
there are three or more of the signal wiring layers, and
the at least one coupling unit includes a plurality of coupling units at different positions in the extending direction in a plurality of spaces between the signal wiring layers.

8. The signal wiring board according to claim 1, wherein
there is a location with a varied number of layers in the extending direction in a plurality of the signal wiring layers.
